(19) United States
(12) Patent Application Publication
(10) Pub. No.: US 2025/0197988 A1
(43) Pub. Date: Jun. 19, 2025

(54) BLACK OXIDIZED SURFACES

(71) Applicant: Vapor Technologies, Inc., Longmonth, CO (US)

(72) Inventor: Bryce Randolph ANTON, Longmont, CO (US)

(73) Assignee: Vapor Technologies, Inc., Longmont, CO (US)

(21) Appl. No.: 18/978,192

(22) Filed: Dec. 12, 2024

Related U.S. Application Data
(60) Provisional application No. 63/610,850, filed on Dec. 15, 2023.

(51) Int. Cl. C23C 14/58; C23C 14/02; C23C 14/14; C23C 14/32

(52) U.S. Cl. CPC C23C 14/5853; C23C 14/025; C23C 14/14; C23C 14/325

(57) ABSTRACT

Methods for producing durable oxide coatings on various substrates are provided. The method involves depositing an oxidizable metal layer, such as zirconium, aluminum, titanium, magnesium, or niobium, onto a substrate using physical vapor deposition techniques, including sputtering, evaporation, or cathodic arc deposition. The oxidizable metal layer is subsequently treated using anodization or micro-arc oxidation (MAO) to convert at least a portion of the layer into a robust oxide coating. The MAO process employs high voltages and current densities in an electrolytic bath containing water, salts, and additives to enhance surface properties. The resulting oxide layer provides exceptional hardness, corrosion resistance, thermal stability, and aesthetic finishes, including a black appearance. The method is compatible with diverse substrates, including metals, alloys, and plastics, enabling applications in aerospace, automotive, consumer electronics, and decorative industries. This approach overcomes limitations of traditional coatings by delivering tailored, high-performance surfaces.

### CROSS-REFERENCE TO RELATED APPLICATIONS

This application claims the benefit of U.S. provisional application Ser. No. 63/610,850 filed Dec. 15, 2023, the disclosure of which is hereby incorporated in its entirety by reference herein.

### TECHNICAL FIELD

In at least one aspect, improved methods that apply a durable coating to a substrate are provided.

### BACKGROUND

Surface oxidation treatments, such as anodization and plasma electrolytic oxidation (PEO), represent crucial advancements in enhancing the durability, aesthetic appeal, and functional properties of metallic surfaces. These processes are widely utilized across various industries, including aerospace, automotive, and consumer electronics, owing to their ability to improve corrosion resistance and mechanical performance. Among the metals commonly subjected to these treatments, aluminum and titanium stand out due to their inherent ability to form robust and protective oxide layers. However, the applicability of these methods extends beyond these two metals. Other materials, including magnesium, niobium, and zirconium, can also undergo similar treatments, with each metal offering unique benefits based on its chemical and physical properties. Notably, under specific conditions tailored for temperature, electrolyte composition, and current density, certain metals can yield a visually striking black oxide deposit. This black oxide layer not only enhances the aesthetic appeal of the surface but also provides functional benefits such as improved wear resistance, thermal stability, and optical properties, making it suitable for high-performance and decorative applications.

Conventionally, oxide treatments like anodization and PEO are predominantly applied to bulk metals and alloys, where the underlying substrate serves as the source of the oxide film. In these cases, the surface of the metal is directly transformed through electrochemical processes to grow an oxide layer with tailored thickness and properties. For instance, aluminum components are commonly anodized or subjected to PEO to generate a hard aluminum oxide layer, which significantly enhances their wear resistance and corrosion protection. However, the application of these treatments to metal coatings deposited on different substrate materials remains a less explored area. Unlike bulk metals, metal coatings involve a distinct set of challenges, including adhesion, uniformity, and compatibility with the underlying substrate. This limitation has restricted the broader adoption of anodization and PEO for coated surfaces, thereby creating an unmet need for advanced methods capable of applying durable and functional oxide films to coated articles. Addressing this gap could unlock new possibilities for achieving high-performance coatings with tailored properties, particularly in industries demanding lightweight, corrosion-resistant, and visually appealing materials.

Accordingly, there is a need for improved methods that apply a durable coating to a substrate.

### SUMMARY

In at least one aspect, the present disclosure provides an improved method for treating a coated article to achieve enhanced surface properties, durability, and aesthetic appeal. The method comprises the application of an oxidizable metal layer over a substrate utilizing a physical vapor deposition technique, such as sputtering, evaporation, or cathodic arc deposition, to ensure precise control over the layer's thickness and uniformity. Following the deposition, the oxidizable metal layer is treated using an electrochemical process, such as anodization or micro-arc oxidation (MAO), to transform at least a portion of the metal layer into an oxide layer. This transformation imparts the coated article with a robust, functional oxide surface that can be tailored for specific applications. In a refinement, the oxide layer may provide benefits such as increased corrosion resistance, wear resistance, thermal stability, and optical properties, with a visually appealing black oxide finish being a particularly advantageous outcome. The disclosed method is adaptable to various substrate materials, including metals, metal alloys, and plastics, enabling its implementation across diverse industrial applications such as aerospace, automotive, consumer electronics, and decorative finishes.

In another aspect, the present disclosure provides durable black oxide coatings primarily based on zirconium oxide, offering a combination of aesthetic appeal and superior functional properties. These advanced coatings, produced through precise treatment methods, exhibit exceptional durability, uniformity, and resistance to wear, corrosion, and thermal degradation. Unlike conventional PVD coatings, these zirconium oxide-based black coatings achieve enhanced performance characteristics that are particularly well-suited for a wide range of consumer products. Applications include plumbing fixtures, sporting goods, and consumer electronics, where the need for a visually striking, uniform, and resilient finish is paramount. The coatings not only elevate the visual quality of these products but also extend their service life by providing robust protection against environmental and mechanical stress. This innovative approach addresses long-standing limitations of traditional coatings, positioning the disclosed zirconium oxide coatings as a valuable advancement for high-performance and decorative applications.

In another aspect, the present disclosure provides durable black oxide coatings that can be effectively applied to a wide variety of substrates, including metals such as steel, brass, and zinc, as well as non-metallic materials like ABS plastic. This versatility makes the disclosed coatings highly adaptable for use in diverse industries, addressing the demand for materials that combine aesthetic excellence with enhanced functional performance. By enabling the application of black oxide coatings on substrates with differing chemical and physical properties, this approach overcomes traditional limitations associated with oxide treatments. The resulting coatings exhibit exceptional adhesion, uniformity, and durability across all substrate types, ensuring consistent performance in demanding environments. Whether applied to metal components requiring high corrosion resistance or plastic surfaces needing a decorative and protective finish, these coatings offer a transformative solution for industries such as automotive, consumer goods, and industrial manufacturing.

In another aspect, the present disclosure provides a method wherein an oxidizable metal layer, such as zirconium (Zr), titanium (Ti), niobium (Nb), aluminum (Al), or magnesium (Mg), is applied to a substrate using precision physical vapor deposition (PVD) techniques. The substrate material may differ from the oxidizable metal layer, allowing for versatile material pairings to suit specific functional and aesthetic requirements. Following the deposition, the coated part undergoes electrochemical treatment, such as anodizing or plasma electrolytic oxidation (PEO), to grow a robust oxide layer on the surface. This oxide layer is tailored to achieve a target black color, valued for its aesthetic appeal and enhanced optical properties; however, the method also allows for customization to produce other surface appearances if desired. By combining the adaptability of PVD techniques with advanced surface oxidation processes, this method delivers durable, high-performance coatings suitable for applications demanding both visual refinement and functional excellence.

In another aspect, a coated substrate formed by the methods set forth herein is provided. The coated substrate includes a substrate and an oxidizable metal layer disposed on the substrate. Characteristically, the oxidizable metal layer is applied using a physical vapor deposition technique Typically, the oxidizable metal layer is composed of a material selected from the group consisting of zirconium, aluminum, titanium, magnesium, niobium, and combinations thereof. The coated substrate further includes an oxide layer formed on at least a portion of the oxidizable metal layer, wherein the oxide layer is produced by treating the oxidizable metal layer through anodization or micro-arc oxidation.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

For a further understanding of the nature, objects, and advantages of the present disclosure, reference should be had to the following detailed description, read in conjunction with the following drawings, wherein like reference numerals denote like elements and wherein:

FIG. 1A is a schematic flowchart depicting a method for applying hard durable coating to a substrate.

FIG. 1B is a schematic flowchart depicting a method for applying hard durable coating to a substrate.

### DETAILED DESCRIPTION

Reference will now be made in detail to presently preferred compositions, embodiments and methods of the present invention, which constitute the best modes of practicing the invention presently known to the inventors. The Figures are not necessarily to scale. However, it is to be understood that the disclosed embodiments are merely exemplary of the invention that may be embodied in various and alternative forms. Therefore, specific details disclosed herein are not to be interpreted as limiting, but merely as a representative basis for any aspect of the invention and/or as a representative basis for teaching one skilled in the art to variously employ the present invention.

Except in the examples, or where otherwise expressly indicated, all numerical quantities in this description indicating amounts of material or conditions of reaction and/or use are to be understood as modified by the word “about” in describing the broadest scope of the invention. Practice within the numerical limits stated is generally preferred. Also, unless expressly stated to the contrary: percent, “parts of,” and ratio values are by weight; the term “polymer” includes “oligomer,” “copolymer,” “terpolymer,” and the like; molecular weights provided for any polymers refers to weight average molecular weight unless otherwise indicated; the description of a group or class of materials as suitable or preferred for a given purpose in connection with the invention implies that mixtures of any two or more of the members of the group or class are equally suitable or preferred; description of constituents in chemical terms refers to the constituents at the time of addition to any combination specified in the description, and does not necessarily preclude chemical interactions among the constituents of a mixture once mixed; the first definition of an acronym or other abbreviation applies to all subsequent uses herein of the same abbreviation and applies mutatis mutandis to normal grammatical variations of the initially defined abbreviation; and, unless expressly stated to the contrary, measurement of a property is determined by the same technique as previously or later referenced for the same property.

It is also to be understood that this invention is not limited to the specific embodiments and methods described below, as specific components and/or conditions may, of course, vary. Furthermore, the terminology used herein is used only for the purpose of describing particular embodiments of the present invention and is not intended to be limiting in any way.

It must also be noted that, as used in the specification and the appended claims, the singular form “a,” “an,” and “the” comprise plural referents unless the context clearly indicates otherwise. For example, reference to a component in the singular is intended to comprise a plurality of components.

The term “comprising” is synonymous with “including,” “having,” “containing,” or “characterized by.” These terms are inclusive and open-ended and do not exclude additional, unrecited elements or method steps.

The phrase “consisting of” excludes any element, step, or ingredient not specified in the claim. When this phrase appears in a clause of the body of a claim, rather than immediately following the preamble, it limits only the element set forth in that clause; other elements are not excluded from the claim as a whole.

The phrase “consisting essentially of” limits the scope of a claim to the specified materials or steps, plus those that do not materially affect the basic and novel characteristic(s) of the claimed subject matter.

With respect to the terms “comprising,” “consisting of,” and “consisting essentially of,” where one of these three terms is used herein, the presently disclosed and claimed subject matter can include the use of either of the other two terms.

The phrase “composed of” means “including” or “comprising.” Typically, this phrase is used to denote that an object is formed from a material.

It should also be appreciated that integer ranges explicitly include all intervening integers. For example, the integer range 1-10 explicitly includes 1, 2, 3, 4, 5, 6, 7, 8, 9, and 10. Similarly, the range 1 to 100 includes 1, 2, 3, 4 . . . 97, 98, 99, 100. Similarly, when any range is called for, intervening numbers that are increments of the difference between the upper limit and the lower limit divided by 10 can be taken as alternative upper or lower limits. For example, if the range is 1.1. to 2.1 the following numbers 1.2, 1.3, 1.4, 1.5, 1.6, 1.7, 1.8, 1.9, and 2.0 can be selected as lower or upper limits.

In the specific examples set forth herein, concentrations, temperature, and reaction conditions (e.g. pressure, pH, etc.) can be practiced with plus or minus 50 percent of the values indicated rounded to three significant figures. In a refinement, concentrations, temperature, and reaction conditions (e.g., pressure, pH, etc.) can be practiced with plus or minus 30 percent of the values indicated rounded to three significant figures of the value provided in the examples. In another refinement, concentrations, temperature, and reaction conditions (e.g., pH, etc.) can be practiced with plus or minus 10 percent of the values indicated rounded to three significant figures of the value provided in the examples.

Throughout this application, where publications are referenced, the disclosures of these publications in their entireties are hereby incorporated by reference into this application to more fully describe the state of the art to which this invention pertains.

Abbreviations:

“ABS” means acrylonitrile butadiene styrene.

“MAO” means micro-arc oxidation.

“PEO” means Plasma Electrolytic Oxidation

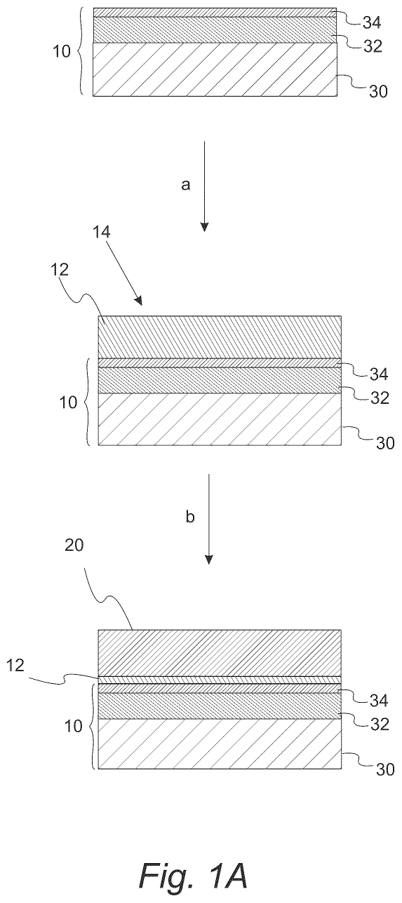

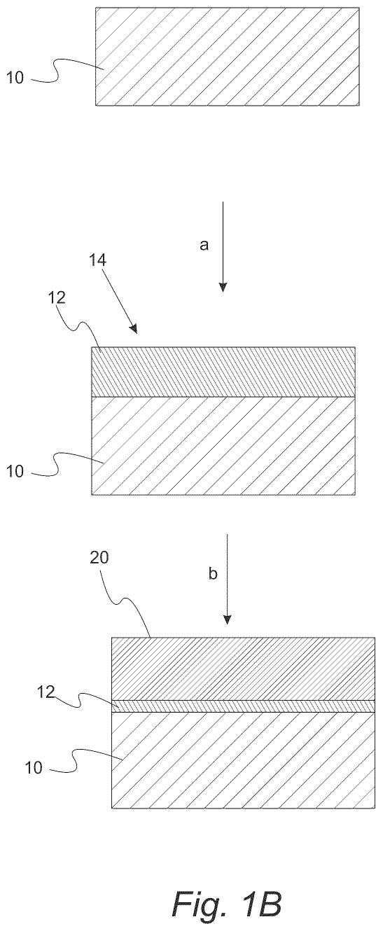

With reference to FIGS. 1A and 1B, schematic flowcharts illustrating methods for producing a coated article with an oxidized surface are provided. As depicted, the process begins with a substrate 10, which is coated with an oxidizable metal layer 12 in step a) to form a metal-coated substrate 14. The oxidizable metal layer 12 may comprise a material selected from zirconium, aluminum, titanium, magnesium, niobium, or combinations thereof, enabling flexibility to tailor the coating properties to specific applications. In a refinement, zirconium is used as the oxidizable metal due to its exceptional ability to form durable and aesthetically appealing oxide layers. In some variations, the substrate 10 may be composed of a different material than the oxidizable metal layer 12, allowing for diverse material pairings. For instance, substrate 10 can include components such as steel, brass, zinc, or ABS plastic, offering broad applicability across various industrial and consumer product domains. The depicted flowcharts in FIGS. 1A and 1B emphasize the adaptability of the method to accommodate multiple material configurations while achieving consistent and high-performance oxidized surfaces.

In another aspect, the oxidizable metal layer 12 has a thickness from 0.1 microns to 10 microns. In a refinement, oxidizable metal layer 12 has a thickness of at least 0.05 microns, 0.1 microns, 0.2 microns, 0.3 microns, 0.4 microns, or 0.5 microns. In a further refinement, oxidizable metal layer 12 has a thickness of at most 100 microns, 50 microns, 12 microns, 10 microns, 1.2 microns, 1 micron, 0.9 microns, 0.8 microns, 0.7 microns, or 0.6 microns.

Still referring to FIGS. 1A and 1B, the oxidizable metal layer 12 is treated in step b) through anodization or micro-arc oxidation (MAO) to convert at least a portion of the metal layer into an oxide layer 20. In a refinement, the remaining oxidizable metal layer 12 is from 0.05 microns to 5 microns. In a further refinement, the thickness of the remaining oxidizable metal layer 12 is at least about 0 microns, 0.0005 microns, 0.005 microns, 0.05 microns, 0.1 microns, 0.2 microns, 0.3 microns, 0.4 microns, or 0.5 microns. In another refinement, the thickness of the remaining oxidizable metal layer 12 is at most about 5 microns, 4 microns, 3 microns, 2 microns, 1.5 microns, 1 micron, 0.9 microns, 0.8 microns, 0.7 microns, 0.5 microns, 0.3 microns, 0.2 microns, or 0.1 microns. In a refinement, the o oxide layer 20 has a thickness from 0.1 microns to 10 microns. In a refinement, oxide layer 20 has a thickness of at least 0.05 microns, 0.1 microns, 0.2 microns, 0.3 microns, 0.4 microns, or 0.5 microns. In a further refinement, oxide layer 20 has a thickness of at most 100 microns, 50 microns, 12 microns, 10 microns, 1.2 microns, 1 micron, 0.9 microns, 0.8 microns, 0.7 microns, or 0.6 microns.

In another aspect, oxide layers formed by anodization or micro-arc oxidation exhibit a range of unique physical properties that enhance their suitability for demanding applications. These layers are exceptionally hard and wear-resistant, with MAO often producing denser, crystalline structures such as corundum (α-alumina) or zirconia for superior durability. The layers provide outstanding corrosion resistance, which can be further improved by post-treatment sealing. Thermal stability is another key feature, with MAO layers excelling in high-temperature environments. The thickness of the oxide layers varies by process, with anodized layers being thinner and smoother (typically a few microns), while MAO layers can reach up to 200 microns and feature a microporous surface that improves adhesion for coatings. Optical properties can also differ, as anodized layers can be transparent and dyeable or dark (i.e., black in visible light), while MAO layers are matte with characteristic colors like black or gray (in visible light),, owing to their porous and rough texture. Both processes result in oxide layers that are chemically inert, electrically insulating, and strongly bonded to the substrate, preventing delamination under mechanical or thermal stress.

Still referring to FIGS. 1A and 1B, micro-arc oxidation (MAO) is a highly effective electrochemical surface treatment technique that involves immersing the metal-coated substrate 14 in an electrolytic bath and applying a high-voltage electric current. The process generates micro-discharges (micro-arcs) between the oxidizable metal layer 12 and the electrolyte, resulting in localized high temperatures often exceeding 10,000° C. and intense electric fields, accompanied by plasma formation at the metal surface. These extreme conditions facilitate rapid oxidation, melting, and re-solidification of the metal surface, creating a dense and wear-resistant oxide layer 20 with tailored thickness, porosity, and composition. MAO is highly customizable, with parameters such as voltage (200-800 volts), current density (0.1 to 0.5 A/cm² or 10-50 A/dm²), treatment time, and electrolyte composition adjustable to achieve specific properties, including enhanced hardness, thermal stability, optical appearance, and porosity. These attributes make MAO and anodization indispensable for applications across aerospace, automotive, consumer electronics, and medical devices. The porousness and roughness of oxide layers formed through micro-arc oxidation enhances functionality and depend on process parameters such as voltage, current density, electrolyte composition, and treatment time. The average pore diameter typically ranges from 0.1 to 10 microns, with pore densities of 10⁴ to 10⁶ pores/cm² and an overall porosity percentage between 10% and 40%. These pores result from localized plasma discharges during the MAO process, with larger pores forming at higher voltages due to more energetic discharges. The surface roughness (Ra) generally ranges from 1 to 15 microns, with peak-to-valley height differences (Rz) of 10 to 50 microns, creating a crater-like morphology characteristic of MAO layers.

The electrolytic bath used in the MAO process typically includes water as a solvent, along with alkaline or alkaline-earth metal salts such as potassium hydroxide, sodium phosphate, or sodium silicate to enhance the conductivity of the electrolyte. Additional additives, including surfactants, stabilizers, and dispersants, can be incorporated to improve the uniformity of the oxide layer and control its structural and functional properties. The process is highly customizable, allowing parameters such as current density, voltage waveform (e.g., direct current, alternating current, or pulsed DC), treatment time, and electrolyte composition to be adjusted to achieve specific characteristics, including hardness, corrosion resistance, thermal stability, and optical appearance. By leveraging these capabilities, MAO enables the production of advanced oxide layers suitable for a wide range of high-performance applications, including aerospace, automotive, and consumer electronics.

Similarly, anodization is another electrochemical process employed to create a protective oxide layer on the surface of certain metals, such as aluminum. In this process, the substrate operates as an anode and is immersed in an electrolyte solution, typically an acidic bath. A cathode, commonly composed of stainless steel or lead, is also placed in the bath. When a direct current (DC) is applied, oxygen ions from the electrolyte combine with the metal atoms at the surface of the oxidizable metal layer 12, forming a uniform and protective layer of metal oxide. Both MAO and anodization processes are versatile, enabling the creation of durable oxide coatings that enhance the functional and aesthetic properties of the coated article.

In another aspect, the oxidizable metal layer 12 is deposited onto the substrate 10 using a physical vapor deposition (PVD) technique, which allows for precise control over the composition, thickness, and uniformity of the applied metal layer. Examples of PVD techniques include, but are not limited to, sputtering, evaporation, cathodic arc deposition, and combinations of these methods. Among these, cathodic arc deposition is particularly advantageous due to its ability to produce dense and adherent coatings with minimal porosity. In the cathodic arc deposition process, a target material is vaporized using a high-current, low-voltage electrical arc, creating a plasma of ionized particles. These ionized particles are then directed toward the substrate 10, where they condense to form the oxidizable metal layer 12. This process not only ensures excellent adhesion to the substrate but also enables the deposition of complex alloy compositions or multilayer structures when needed. The versatility and effectiveness of cathodic arc deposition make it a preferred choice for creating high-quality oxidizable metal coatings suited for subsequent surface treatment processes such as anodization or micro-arc oxidation.

In another aspect, the substrate 10 is composed of a component selected from the group consisting of metals, metal alloys, plastics, and combinations thereof, providing a wide range of material compatibility for various applications. This versatility allows the disclosed methods to be applied across industries requiring tailored surface treatments for diverse substrate types. In a refinement, substrate 10 is specifically composed of a component selected from the group consisting of steel, brass, zinc, ABS plastic, or combinations thereof. These materials are particularly advantageous due to their mechanical strength, chemical stability, and widespread use in structural and functional applications. For example, steel and brass substrates offer excellent load-bearing capabilities and corrosion resistance, while zinc substrates provide lightweight and cost-effective solutions. ABS plastic, on the other hand, is valued for its lightweight properties, ease of molding, and suitability for decorative and consumer goods applications. By accommodating this diverse selection of substrate materials, the disclosed method ensures adaptability to a broad spectrum of industrial and commercial needs.

Referring to FIG. 1A, substrate 10 includes a base substrate 30 that serves as the foundational layer for subsequent coatings and can be optionally coated with one or more primer metal layers prior to the application of the oxidizable metal layer 12. Examples of primer layers includes, but are not limited to nickel, chromium, zinc, copper, titanium, cobalt, aluminum, molybdenum, and silver, and alloys thereof. In refinement, the one or more primer metal layers have a total thickness from about 50 nm to 10000 nm. In a further refinement, the one or more primer metal layers have a total thickness of at least 20 nm, 50 nm, 100 nm, 200 nm, 300 nm, 500 nm, or 1000 nm. In another refinement, the thickness is at most about 10000 nm, 5000 nm, 2000 nm, 1500 nm, 1200 nm, 1000 nm, or 800 nm. A base substrate 30, in this context, refers to an uncoated substrate, which can be composed of either metal or plastic. Examples of suitable materials for the base substrate 30 include, but are not limited to, steel, brass, zinc, titanium, or ABS plastic, offering flexibility for various industrial and functional applications. In a refinement, the base substrate 30 is sequentially coated with a first metal primer layer 32, which is disposed over and typically directly contacts the base substrate 30, and a second metal primer layer 34, which is disposed over and typically contacts the first primer layer. These primer layers enhance the adhesion, uniformity, and durability of the oxidizable metal layer 12. For instance, in one example, the first metal primer layer 32 is composed of nickel (i.e., a nickel layer), and the second metal primer layer 34 is composed of chromium (i.e., a chromium layer), forming a robust foundation for the subsequent surface treatments. In a refinement, the first and second metal primer layers each have a thickness from about 25 nm to about 5000 nm. In a further refinement, the thickness of each layer is at least about 25 nm, 50 nm, 100 nm, 200 nm, 300 nm, 400 nm, or 500 nm. In another refinement, the thickness of each layer is at most about 5000 nm, 3000 nm, 2000 nm, 1500 nm, 1200 nm, 1000 nm, or 800 nm.

Referring to FIG. 1B, substrate 10 may also be a monolithic component that is not intentionally coated with primer metal layers before applying the oxidizable metal layer 12. This monolithic configuration simplifies the preparation process while still enabling the application of the disclosed coating methods. Substrate 10, in this embodiment, is composed of a single, uniform material that can include metals, metal alloys, plastics, or combinations thereof. In a refinement, substrate 10 is specifically selected from components such as steel, brass, zinc, or ABS plastic, ensuring compatibility with the physical vapor deposition (PVD) techniques and subsequent oxidation processes. This approach broadens the versatility of the method, enabling its use across a wide range of substrates while maintaining high performance and durability.

In another aspect, the oxidizable metal layer 12 is subjected to anodization or micro-arc oxidation (MAO) to convert at least a portion of the metal layer into an oxide layer 20. These electrochemical surface treatments enhance the physical and chemical properties of the coated article, producing a durable oxide layer with tailored functional and aesthetic characteristics. The anodization process leverages an acidic electrolyte and direct current to grow a uniform and protective oxide layer, while MAO utilizes high-voltage discharges in an electrolytic bath to create localized oxidation through intense electric fields and thermal effects. Together, these processes ensure the production of robust and high-quality oxide coatings suitable for diverse industrial and commercial applications.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

What is claimed is:

1. A method for treating a coated article, the method comprising:
a) applying an oxidizable metal layer over a substrate by a physical vapor deposition technique; and
b) treating the oxidizable metal layer by anodization or micro-arc oxidation to convert at least a portion of the oxidizable metal layer to an oxide layer.

2. The method of claim 1, wherein the oxidizable metal layer is composed of zirconium, aluminum, titanium, magnesium, niobium, and combinations thereof.

3. The method of claim 1, wherein the oxidizable metal layer is composed of zirconium.

4. The method of claim 1, wherein the substrate is composed of a different material than the oxidizable metal layer.

5. The method of claim 1, wherein the oxidizable metal layer has a thickness from 0.1 microns to 10 microns.

6. The method of claim 1, wherein the physical vapor deposition technique is selected from the group consisting of sputtering, evaporation, cathodic arc deposition, and combinations thereof.

7. The method of claim 1, wherein the physical vapor deposition technique is cathodic arc deposition.

8. The method of claim 1, wherein the substrate is composed of a component selected from the group consisting of metals, metal alloys, plastics, and combinations thereof.

9. The method of claim 1, wherein the substrate is composed of a component selected from the group consisting of steel, brass, zinc, titanium, ABS plastic, and combinations thereof.

10. The method of claim 1, wherein the oxidizable metal layer is treated by micro-arc oxidation to convert at least a portion of the oxidizable metal layer to an oxide layer.

11. The method of claim 1, wherein the substrate includes a base substrate coated with one or more primer metal layers prior to applying the oxidizable metal layer.

12. The method of claim 11, wherein the base substrate is coated with a first metal primer layer that contacts the substrate and a second metal primer layer that contacts the first metal primer layer.

13. The method of claim 12, wherein the first metal primer layer is a nickel layer and the second metal primer layer is a chromium layer.

14. The method of claim 12, wherein the substrate is monolithic.

15. A method for treating a coated article, the method comprising:
a) applying an oxidizable metal layer over a substrate by a physical vapor deposition technique; and
b) treating the oxidizable metal layer by micro-arc oxidation to convert at least a portion of the oxidizable metal layer to an oxide layer.

16. The method of claim 15, wherein the oxidizable metal layer is composed of zirconium, aluminum, titanium, magnesium, niobium, and combinations thereof.

17. The method of claim 15, wherein the oxidizable metal layer is composed of zirconium.

18. The method of claim 15, wherein the physical vapor deposition technique is selected from the group consisting of sputtering, evaporation, cathodic arc deposition, and combinations thereof.

19. The method of claim 15, wherein the substrate is composed of a component selected from the group consisting of metals, metal alloys, plastics, and combinations thereof.

20. The method of claim 15, wherein the substrate includes a base substrate coated with one or more primer metal layers prior to applying the oxidizable metal layer.

21. The method of claim 20, wherein the base substrate is coated with a first metal primer layer that contacts the substrate and a second metal primer layer that contacts the first metal primer layer.

22. The method of claim 21, wherein the first metal primer layer is a nickel layer and the second metal primer layer is a chromium layer.

23. A coated substrate, comprising:
a substrate;
an oxidizable metal layer disposed on the substrate, wherein the oxidizable metal layer is applied using a physical vapor deposition technique and comprises a material selected from the group consisting of zirconium, aluminum, titanium, magnesium, niobium, and combinations thereof; and
an oxide layer formed on at least a portion of the oxidizable metal layer, wherein the oxide layer is produced by treating the oxidizable metal layer through anodization or micro-arc oxidation.

24. The coated substrate of claim 23, wherein the substrate is selected from the group consisting of metals, metal alloys, plastics, and combinations thereof.

25. The coated substrate of claim 23, wherein the physical vapor deposition technique is selected from the group consisting of sputtering, evaporation, cathodic arc deposition, and combinations thereof.

26. The coated substrate of claim 23, wherein the oxidizable metal layer is applied over one or more primer metal layers, the one or more primer metal layers comprising:
a first metal primer layer disposed over the substrate; and
a second metal primer layer disposed over the first metal primer layer.

27. The coated substrate of claim 26, wherein the first metal primer layer comprises nickel, and the second metal primer layer comprises chromium.

28. The coated substrate of claim 23, wherein the oxide layer comprises zirconium oxide and exhibits a black appearance.
